(19) United States
(12) Patent Application Publication
(10) Pub. No.: US 2019/0265409 A1
(43) Pub. Date: Aug. 29, 2019

(54) OPTICAL AMPLIFIER

(71) Applicant: Elenion Technologies, LLC, New York, NY (US)

(72) Inventors: Thomas Wetteland Baehr-Jones, Arcadia, CA (US); Saeed Fathololoumi, San Gabriel, CA (US)

(21) Appl. No.: 15/903,835

(22) Filed: Feb. 23, 2018

(51) Int. Cl. G02B 6/122; H01S 5/10; H01S 5/50; H01S 5/065

(52) U.S. Cl. CPC G02B 6/1228; H01S 5/1014; H01S 5/0652; H01S 5/50; H01S 5/101

(57) ABSTRACT

Conventional integrated optical amplifiers, which combine different types of platforms, e.g. silicon photonic integrated circuit for the device layer, and a Group III-V material for the gain medium, typically include a curved waveguide extending through the gain medium coupled to waveguides in the main device layer. Unfortunately, the radius of curvature of the curved waveguide becomes a limiting factor for both size and amplification. Accordingly, an optical amplifier which eliminates the need for the curved waveguide by including a coupler for splitting an input optical signal into two sub-beams, for passage through the gain medium, and a reflector for reflecting the two sub-beams back through the gain medium to the coupler for recombination, would be a welcome improvement. A phase tuner may also be provided to ensure coherence cancellation between the two sub-beams to maximize output and minimize back reflection without requiring an isolator.

### TECHNICAL FIELD

The present invention relates to an optical amplifier, and in particular to an integrated optical amplifier utilizing a reflective semiconductor optical amplifier (RSOA).

### BACKGROUND

Conventional hybrid integrated optical amplifiers, which combine one type of platform for the main device layer, e.g. silicon photonic integrated circuit, and a different type for the gain medium, e.g. Group III-V material, typically require a 180° curved waveguide in the gain medium, so that the input into and the output from the gain medium are provided at a single mating surface with the main device layer. Unfortunately, the radius of curvature of the curved waveguide must be kept relatively large to ensure proper confinement and controlled amplification. Isolators are often used to minimize light reflecting back into the light source; however, isolators are not easily integrated into photonic integrated circuits.

An object of the present invention is to overcome the shortcomings of the prior art by eliminating the need for the 180° curved waveguides and isolators by providing an optical amplifier including a coupler for splitting an input optical signal into two sub-beams, for passage through a gain medium, and a reflector for reflecting the two sub-beams back through the gain medium to the coupler. A phase tuner may also be provided to ensure coherence cancellation between the two sub-beams to maximize output and minimize back reflection without requiring an isolator.

### SUMMARY OF THE INVENTION

Accordingly, the present invention relates to an optical amplifier device comprising:

an input port for launching an input optical signal;

a coupler including an input optically coupled to the input port, first and second input/outputs, and an output, wherein the coupler is capable of separating the input optical signal into first and second sub-beams, and outputting the first and second sub-beams via the first and second input/outputs, respectively;

a gain medium optically coupled to the first and second input/outputs, capable of amplifying the first and second sub-beams forming first and second amplified sub-beams;

a reflector for reflecting the first and second amplified sub-beams back to the coupler;

an output port optically coupled to the output for outputting the amplified optical signal; and

a first phase shifter capable of adjusting the phase of the first sub-beam and the first amplified sub-beam, so that the first amplified sub-beam combines coherently with the second amplified sub-beam causing coherent cancellation therebetween, whereby substantially all of the amplified optical signal exits the output and the output port;

wherein the coupler is further capable of combining the first and second amplified sub-beams into the amplified optical signal, and outputting the amplified optical signal via the output to the output port.

Another aspect of the present invention relates to an optical amplifier device comprising:

a first input port for launching a first input optical signal;

a first coupler including first, second, third and fourth branches, the first branch optically coupled to the first input port, wherein the first coupler is capable of separating the first input optical signal into first and second sub-beams onto the second and third branches, respectively;

a first gain medium optically coupled to the second and third branches, capable of amplifying the first and second sub-beams forming first and second amplified sub-beams, and

a first reflector for reflecting the first and second amplified sub-beams back to the coupler; and

a first output port optically coupled to the fourth branch for outputting a first amplified optical signal;

a first phase shifter capable of adjusting the phase of the first sub-beam and the first amplified sub-beam, so that the first amplified sub-beam combines coherently with the second amplified sub-beam causing coherent cancellation therebetween, whereby substantially all of the first amplified optical signal exits the fourth branch and the first output port;

wherein the first coupler is further capable of combining the first and second amplified sub-beams into the first amplified optical signal, and outputting the first amplified optical signal via the fourth branch to the first output port;

a second input port for launching a second input optical signal;

a second coupler including fifth, sixth, seventh and eighth branches, the fifth branch optically coupled to the second input port, wherein the second coupler is capable of separating the second input optical signal into third and fourth sub-beams onto the sixth and seventh branches, respectively;

a second gain medium optically coupled to the sixth and seventh branches, capable of amplifying the third and fourth sub-beams forming third and fourth amplified sub-beams;

a second reflector for reflecting the third and fourth amplified sub-beams back to the second coupler; and

a second output port optically coupled to the eighth branch for outputting a second amplified optical signal;

a second phase shifter capable of adjusting the phase of the third sub-beam and the third amplified sub-beam, so that the third amplified sub-beam combines coherently with the fourth amplified sub-beam causing coherent cancellation therebetween, whereby substantially all of the second amplified optical signal exits the eighth branch and the second output port;

wherein the second coupler is further capable of combining the third and fourth amplified sub-beams into the second amplified optical signal, and outputting the second amplified optical signal via the eighth branch to the second output port.

### BRIEF DESCRIPTION OF THE DRAWINGS

The invention will be described in greater detail with reference to the accompanying drawings which represent preferred embodiments thereof, wherein:

FIG. 1a is a schematic plan view of an optical amplifier in accordance with an embodiment of the present invention;

FIG. 1b is a schematic plan view of an optical amplifier in accordance with another embodiment of the present invention;

FIG. 1c a schematic plan view of an optical amplifier in accordance with another embodiment of the present invention;

FIG. 1d a schematic plan view of an optical amplifier in accordance with another embodiment of the present invention;

FIG. 2a a schematic plan view of an optical filter in accordance with an embodiment of any one of the optical amplifiers of FIGS. 1a to 1d;

FIG. 2b a schematic plan view of an optical filter in accordance with an embodiment of any one of the optical amplifiers of FIGS. 1a to 1d;

FIG. 3 a schematic plan view of an optical amplifier in accordance with another embodiment of the present invention; and

FIG. 4 a schematic plan view of an optical amplifier in accordance with another embodiment of the present invention.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art.

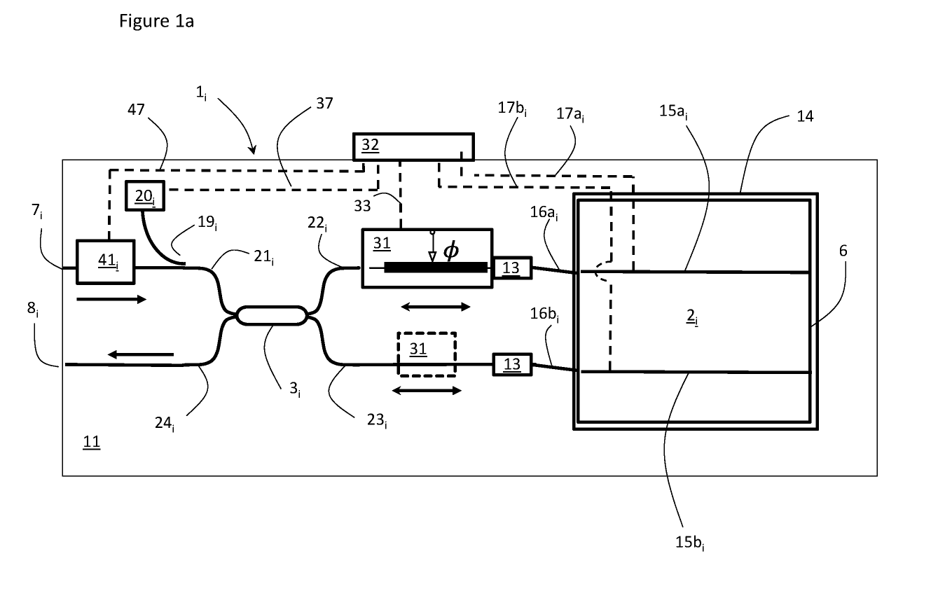

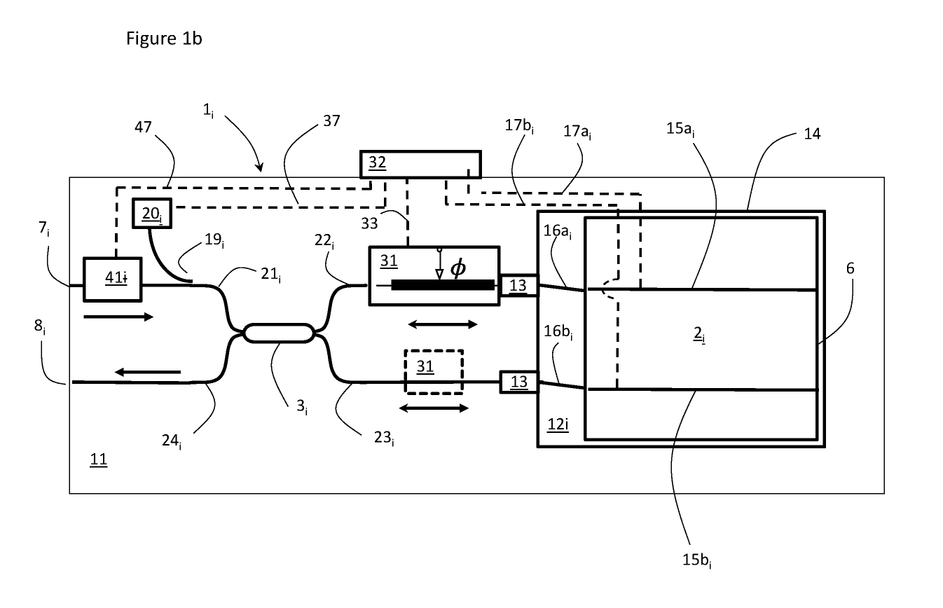

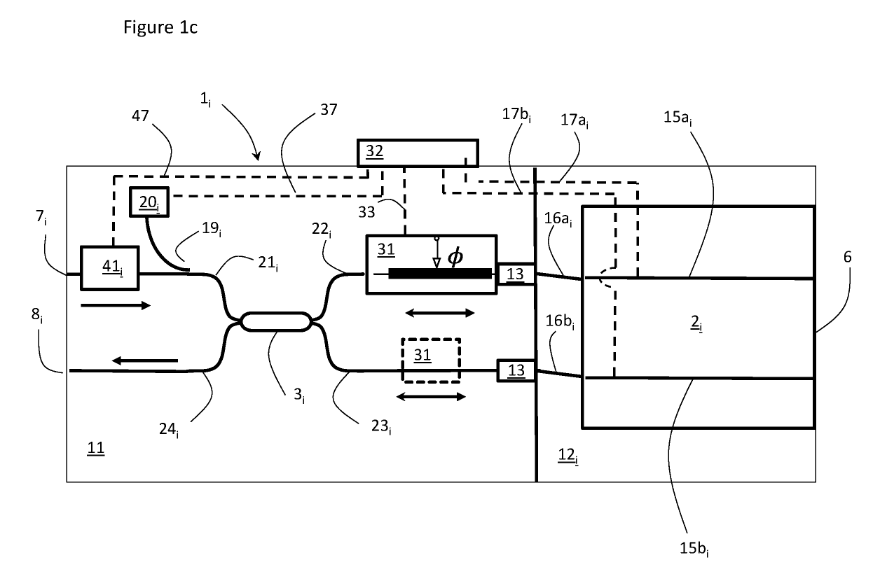

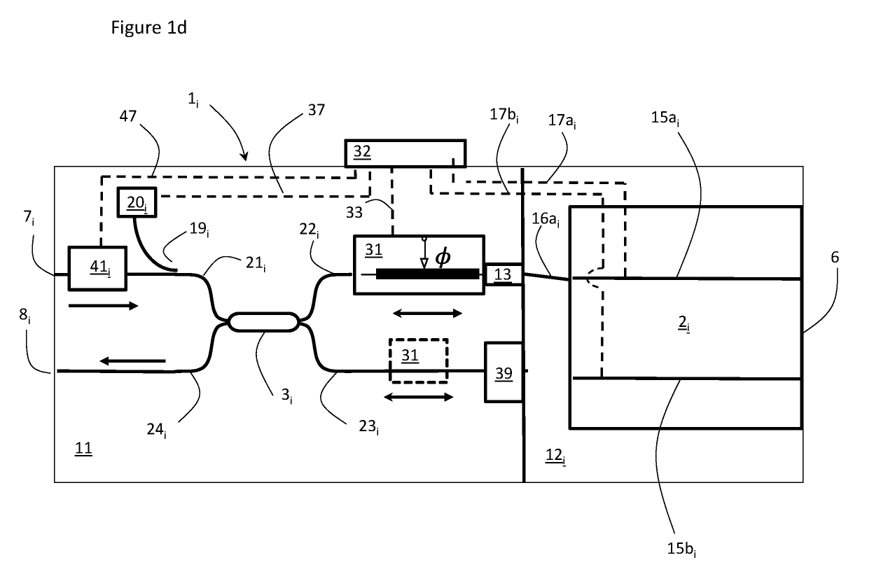

With reference to FIGS. 1a to 1c, an amplifier device of an exemplary embodiment of the present invention includes one or more amplifiers 1ᵢ, each including a gain medium 2ᵢ, and a coupler 3ᵢ. (i being a natural number) A reflector 6, e.g. a reflective surface, is provided on or adjacent to the gain medium 2ᵢ for reflecting light back to the coupler 3ᵢ. An input port 7ᵢ and an output port 8ᵢ are provided for receiving and transmitting light to and from the amplifier provided on a photonic chip 11.

The gain medium 2ᵢ may comprise any suitable amplification material, e.g. a suitable group gain material, such as InP, GaAs and GaN based materials, in particular a reflective semiconductor optical amplifier (RSOA), which may be based on bulk, quantum well or quantum dot material. The gain medium 2ᵢ may be provided on the photonic integrated chip 11, as illustrated in FIGS. 1a and 1b, or the gain medium 2ᵢ may be provided on a separate gain chip 12ᵢ with the remaining elements, i.e. the coupler 3ᵢ, provided on the photonic chip 11, as illustrated in FIG. 1c. The gain medium chip 12ᵢ, e.g. a RSOA, may also be placed, e.g. flip-chip bonded, onto the photonic integrated chip 11, as illustrated in FIG. 1b, or the gain medium 2ᵢ may be grown onto the photonic integrated chip 11 to form the amplifier 1ᵢ defined in the device layer formed thereon, as illustrated in FIG. 1a.

The photonic integrated chip 11 may include a separate substrate with a semiconductor, e.g. silicon, device layer formed thereon, which includes the coupler 3₁ or the couplers 3₁-3ₙ and all connecting waveguides. Ideally the photonic integrated chip 11 comprises a silicon on insulator (SOI) structure including an upper silicon device layer, a middle silicon dioxide cladding layer, and a bottom silicon substrate. The advantage of this arrangement is that electrical controls on the photonic integrated chip 11 may control the properties of the amplifier 1, e.g. wavelength.

When the gain medium 2ᵢ is embedded within the semiconductor photonic integrated chip 11, as in FIGS. 1a and 1b, the connecting waveguides (16aᵢ and 16bᵢ) may be defined in either the photonic chip (e.g. SOI) material (See FIG. 1a) or the gain medium material (e.g. InP) (See FIG. 1b). During fabrication, a pit 14 may be etched from the device layer down to the substrate, followed by epitaxial growth of the gain medium 2ᵢ (FIG. 1a) or placement of the gain medium chip 12ᵢ within the pit 14 (FIG. 1b). The cladding (oxide) layer may be removed from the photonic integrated chip 11 in order to improve the thermal conductivity between the gain medium 2ᵢ and the substrate, and to match the height of the gain medium 2ᵢ with the semiconductor device layer. The gain medium 2ᵢ or the gain medium chip 12ᵢ may be bonded to electrical contacts (metal or doped semiconductor), which are connected to metal terminals for connecting with external control and/or power, as hereinafter described.

Each optical coupler 3ᵢ may include a first port or branch 21ᵢ on one side optically coupled to the input port 7ᵢ, second and third ports or branches 22ᵢ and 23ᵢ on an opposite side optically coupled to the gain medium 2ᵢ, and a fourth port or branch 24ᵢ on the one side optically coupled to the output port 8ᵢ. The first and fourth ports or branches 21 and 24 may be optically coupled to additional optical elements in the device layer of the photonic integrated chip 11 and/or to an edge of the photonic integrated chip 11. The terms optically coupled or coupled are intended to mean connected for the sake of transmitting light therebetween, typically directly connected or utilizing some form of waveguide structure, e.g. integrated waveguides in the device layer, with or without other intermediate optical elements therebetween. The optical coupler 3ᵢ, e.g. a 2×2 directional coupler (DC), may be connected to the gain medium 2ᵢ in order to split an incoming beam of light into two sub-beams, one sub-beam including a first percentage, e.g. 40%-60%, ideally 50%, of the power directed to a first channel 15aᵢ of the gain medium 2ᵢ, and a second sub-beam including a second percentage, e.g. 40%-60%, ideally, 50% (or −3 dB) directed to the second channel 15bᵢ of the gain medium 2ᵢ. The coupling ratio may be optimized to trade for coupling losses in the device layer and amplification imbalances in the two waveguide channels 15a and 15b.

One or more I/O waveguides 16aᵢ and 16bᵢ, from the gain medium 2ᵢ may be angled at a small acute angle to a normal from the output facet of the gain medium 2ᵢ, e.g. by 5° to 15°, ideally by 9°, and include an anti-reflection coating to reduce the back reflection at the output facet.

The reflector 6 may be comprised of a reflective surface on the RSOA, a reflective surface or coating in the pit housing the gain medium 2ᵢ, or on a surface or coating of the photonic chip 11 or the gain medium chip 12ᵢ, such as an outer edge of the photonic chip 11, as illustrated in FIG. 1a. The reflector 6 may also comprise an alternate optical reflector, e.g. a grating, ring resonator, or some other wavelength filter element integrated into the photonic chip 11, the gain medium 12 or a separate reflector chip (not shown). Any combination of photonic chip 11, gain medium 2ᵢ/gain chip 12ᵢ arrangement, and reflective surface 6 arrangement is within the scope of the invention.

An optical coupler 13 may be provided for coupling the light between the gain medium 2ᵢ, in particular from the gain medium chip 12ᵢ, and the device layer on the photonic chip 11, in particular the coupler 3ᵢ. Due to the large mode mismatch between the I/O waveguides 16aᵢ and 16bᵢ (or the waveguide channels 15aᵢ and 15bᵢ) from the gain medium 2ᵢ and the waveguides in the device layer of the photonic chip 11, the optical coupler 13 may comprise an optical spot-size converter (SSC), which may be provided in the device layer of the photonic chip 11 to reduce the coupling loss between the gain medium 2ᵢ and the photonic chip 11. Alternatively or in addition, the I/O waveguides 16aᵢ and 16bᵢ may include a tapering width and or height for expanding the mode reentering the gain medium 2ᵢ and for contracting the mode leaving the gain medium chip 12ᵢ.

One of more phase shifters or phase tuning sections 31 may be provided in or between the optical coupler 3ᵢ and the gain medium 2ᵢ, coupled to one or both branches 22 and 23, as illustrated in FIGS. 1a and 1b. Each phase tuning section 31 may comprise any form of suitable phase tuning device, e.g. thermo-optic, electro-optic etc. The phase tuning section 31 may be controlled by an external controller 32, via control line 33, to control, e.g. the index of refraction or the effective optical length of the waveguide, i.e. the relative phase of the first and second sub-beams, whereby the first and second sub-beams are substantially correctly phased so that when the first and second amplified sub-beams return to the coupler 3ᵢ, the coupler 3ᵢ combines the first and second amplified sub-beams coherently, so that coherent cancellation occurs, and substantially all of the combined amplified output beam is transmitted to the fourth port or branch 24ᵢ and subsequently the output port 8ᵢ, and substantially none of the combined amplified output beam is transmitted back to the first port or branch 21 and subsequently to the input port 7ᵢ. The phase tuner, i.e. the phase tuning, may be provided by alternative means, e.g. in the coupler 3ᵢ or in the gain medium 2ᵢ or gain chip 12ᵢ.

To ensure the amplitude of each of the sub-beams is substantially the same or at a desired level relative to each other when combining in the coupler 3ᵢ to minimize back reflection at the input port 7ᵢ, the controller 32 may also independently adjust or tune the drive current, i.e. the amplification, provided to each channel 15aᵢ and 15bᵢ of the gain medium 2i via control lines 17aᵢ and 17bᵢ, respectively. The tuning of the drive current may also act as or act in conjunction with the phase tuner 31.

An optical sensor may be provided between the input port 7ᵢ and the coupler 3ᵢ for detecting an amount of back reflection from the gain medium 2ᵢ. The optical sensor may include a monitor tap 19, ideally in the form of a directional coupler, provided on the waveguide between the first port 21ᵢ and the input port 7ᵢ for separating off a small test portion, e.g. <5%, of the return light and delivering the test portion to a photodetector 20, to provide a measure of back reflection from the amplifier 1ᵢ. The controller 32 receives the measure of the back reflection via control line 37, and may tune the phase tuner 31 and/or the drive currents to the channels 15a and 15b to minimize the back reflection at the input port 7ᵢ, and therefore maximize the output power in the amplified output beam at the output port 8ᵢ.

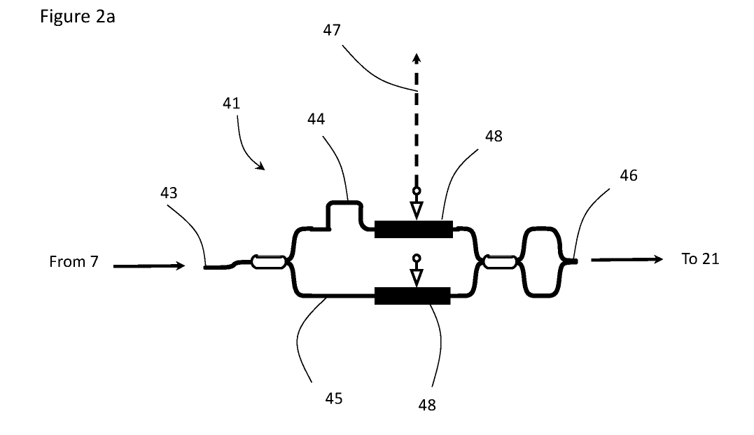

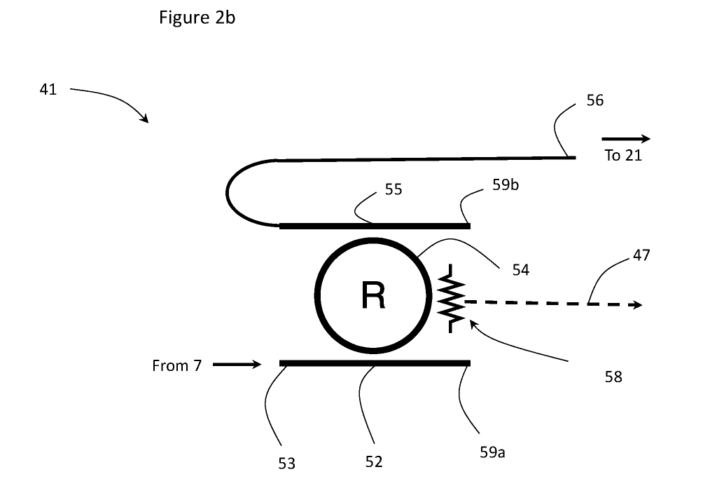

An optical filter 41ᵢ may be provided, ideally between the input port 7ᵢ and the first port or branch 21ᵢ, for passing one or more selected optical wavelengths in the input optical signal and filtering out unwanted wavelengths, prior to amplification in the gain medium 2ᵢ. With reference to FIG. 2a, the optical filter 41ᵢ may comprise an unbalance Mach Zehnder interferometer including an input 43 optically coupled to the input port 7ᵢ, first and second arms 44 and 45, and an output 46 optically coupled to the first port or branch 21ᵢ. Phase tuners 48, e.g. heaters, may be provided in one or both arms 44 and 45 for tuning the passband of the filter 41ᵢ, via control line 47. With reference to FIG. 2b, the optical filter 41 may comprise a ring resonator including an input waveguide 52 with an input port 53 optically coupled to the input port 7ᵢ, at least one ring 54, and an output waveguide 55 with an output port 56 optically coupled to the first port or branch 21ᵢ. Phase tuners 58, e.g. heaters, may be provided in one or both arms 44 and 45 for tuning the passband of the filter 41ᵢ, via control line 47. Additional monitor ports 59a and 59b may be available for monitoring light going into (59a) and going out of (59b) the filter 41ᵢ.

With reference to FIG. 1d, an alternative embodiment for an amplifier 1ᵢ, may include all of the elements and possible variations of the previous embodiments, except the third port or branch 23ᵢ is optically coupled with a beam dump 39 instead of the gain medium 2ᵢ. The beam dump 39 prevents the second sub-beam from returning to the coupler 3ᵢ, whereby the first sub-beam may be divided between the first and fourth ports 21 and 24, respectively.

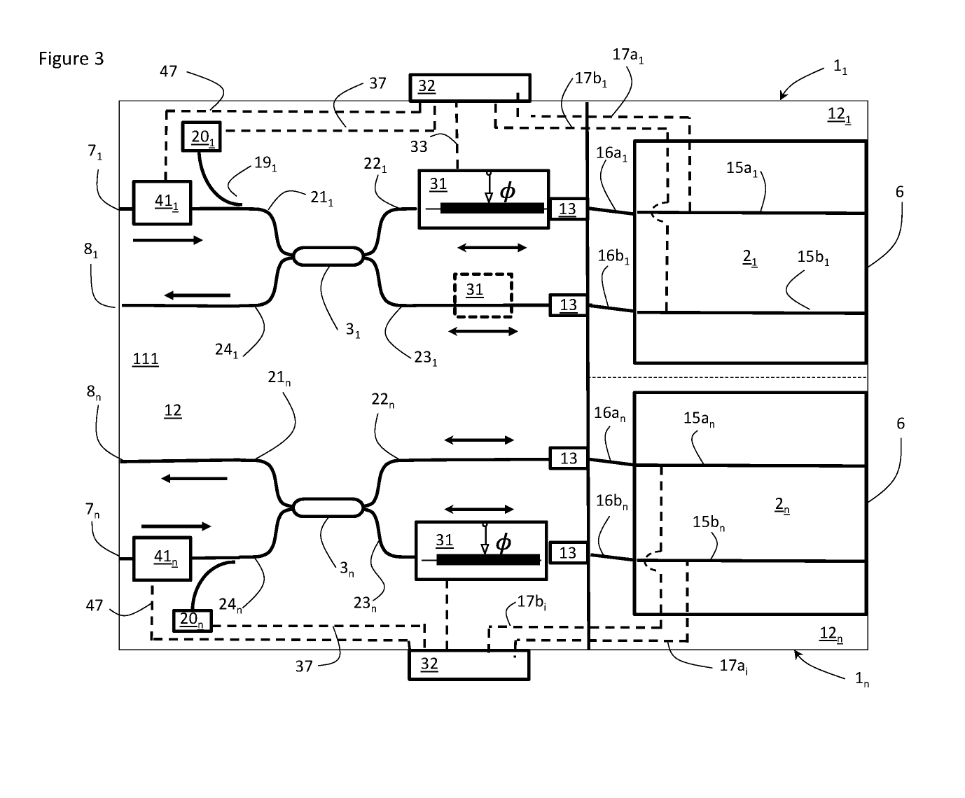

In another embodiment, illustrated in FIG. 3 an array of amplifiers 1₁ to 1ₙ (n equal to a plurality, e.g. 2 or more) are provided on the same photonic chip 111, each amplifier 1₁ to 1ₙ with a separate gain mediums 2₁-2ₙ. An array of the elements, e.g. filters 41, phase tuning elements 31 and couplers 3₁-3ₙ may be provided on the single photonic chip 111, while a plurality of gain mediums 2₁ to 2ₙ may be provided, as in hereinbefore described with reference to FIGS. 1a to 1c. For example, an array of separate gain mediums 2₁-2ₙ, i.e. for amplifying a plurality of different wavelengths, may be provided on a plurality of different gain chips 12₁-12ₙ, all of which are fixed to the single photonic chip 111. The gain mediums 2₁-2ₙ may be the same material capable of amplifying the different wavelengths or the gain mediums 2₁-2ₙ may be different materials capable of amplifying the different wavelengths.

Alternatively, a plurality of separate gain mediums 2₁ to 2ₙ may be grown onto the single photonic chip 111 or a plurality of gain medium chips 12₁ to 12ₙ, e.g. a RSOA, may be placed, e.g. flip-chip bonded, onto the single photonic chip 111 to form the amplifiers 1₁ to 1ₙ defined in the device layer formed thereon, as hereinbefore defined with reference to FIGS. 1a and 1b, respectively. The gain medium chips 11₁ to 11ₙ may also be placed into separate pits 14 in the device layer for coupling with additional couplers 3₂-3ₙ, as described herein. Accordingly, the gain mediums 2₁ to 2ₙ are embedded within the semiconductor photonic chip 111, enabling the waveguides 16a₁ to 16aₙ and 16b₁ to 16bₙ to be defined in either the photonic chip (e.g. SOI) material or the gain medium material (e.g. InP). During fabrication, each pit 14 may be etched from the device layer down to the substrate, followed by epitaxial growth of the gain mediums 2₁ to 2ₙ or placement of the gain medium chips 12₁ to 12ₙ within the pits 14. The cladding (oxide) layer may be removed from the photonic integrated chip 111 in order to improve the thermal conductivity between the gain mediums 2₁ to 2ₙ and the substrate, and to match the height of the gain mediums 2₁ to 2ₙ with the semiconductor device layer. The gain mediums 2₁ to 2ₙ or the gain medium chips 12₁ to 12ₙ may be bonded to electrical contacts (metal or doped semiconductor), e.g. control lines 17a₁ to 17aₙ and 17b₁ to 17bₙ which are connected to metal terminals for connecting with external control and/or power.

The photonic integrated chip 111 may include a separate substrate with a semiconductor, e.g. silicon, device layer formed thereon, which includes the couplers 3₁ to 3ₙ and all connecting waveguides. Ideally the photonic integrated chip 111 comprises a silicon on insulator (SOI) structure including an upper silicon device layer, a middle silicon dioxide cladding layer, and a bottom silicon substrate. The advantage of this arrangement is that electrical controls on the photonic integrated chip 111 may control the properties of the amplifiers 1₁ to 1ₙ, e.g. wavelength and gain.

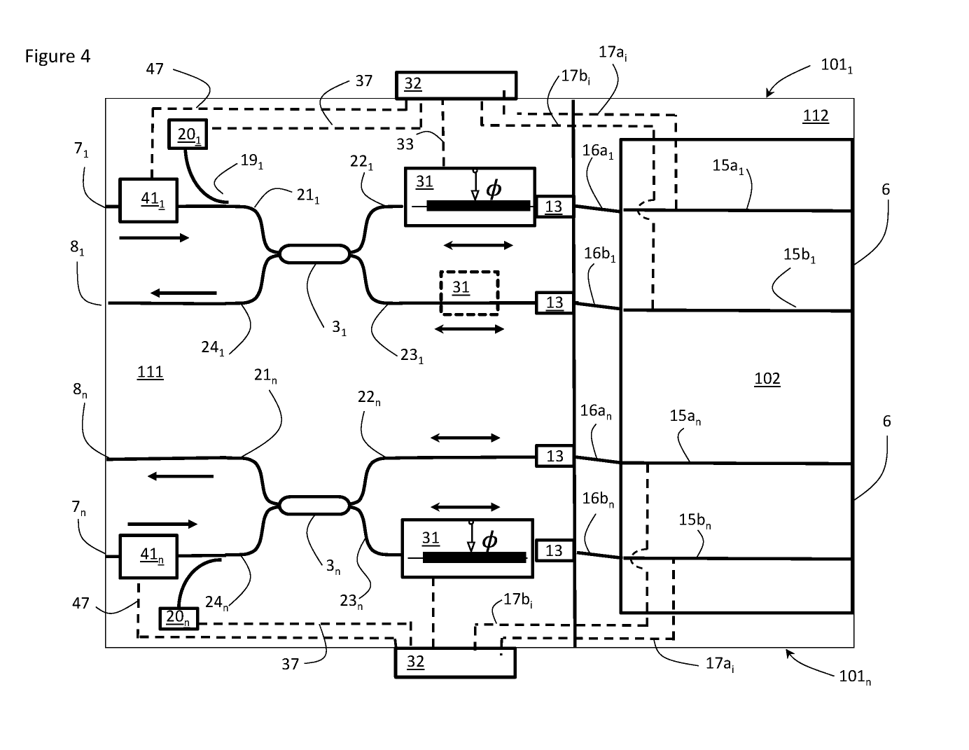

In another embodiment, illustrated in FIG. 4 an array of amplifiers 101₁ to 101ₙ (n equal to a plurality, e.g. 2 or more) are provided on the same photonic chip 111, each amplifier 101₁ to 101ₙ with a same gain medium 102. An array of the elements, e.g. filters 41, phase tuning elements 31 and couplers 3₁-3ₙ, may be provided on the single photonic chip 111, while the game medium 102 may be provided, as in hereinbefore described with reference to FIGS. 1a to 1c. For example, the gain mediums 102 may be provided on a different gain chip 112, which are fixed to the single photonic chip 111, as illustrated in FIG. 4. Each optical filter 41₁ to 41ₙ may be tuned by the controllers 32 to pass a different wavelength channel, i.e. center wavelength, within the amplification range of the gain medium 102, for amplifying a plurality of different wavelengths channels at the same time.

Alternatively, the gain mediums 102 may be grown onto the single photonic integrated chip 111 or a single gain medium chip 112, e.g. a RSOA, may be placed, e.g. flip-chip bonded, onto the single photonic integrated chip 111 to form the amplifiers 101₁ to 101ₙ defined in the device layer formed thereon, as hereinbefore defined with reference to FIGS. 1a and 1b, respectively. The gain medium chip 112 may also be placed into a pit 14 in the device layer for coupling with additional couplers 3₂-3ₙ, as described herein. Accordingly, the gain medium 102 is embedded within the semiconductor photonic integrated chip 111, enabling the waveguides 16a₁ to 16aₙ and 16b₁ to 16bₙ to be defined in either the photonic chip (e.g. SOI) material or the gain medium material (e.g. InP). During fabrication, the pit 14 may be etched from the device layer down to the substrate, followed by epitaxial growth of the gain medium 102 or placement of the gain medium chip 112 within the pit 14. The cladding (oxide) layer may be removed from the photonic integrated chip 111 in order to improve the thermal conductivity between the gain medium 102 and the substrate, and to match the height of the gain medium 102 with the semiconductor device layer. The gain medium 102 or the gain medium chips 112 may be bonded to electrical contacts (metal or doped semiconductor), e.g. control lines 17a₁ to 17aₙ and 17b₁ to 17bₙ which are connected to metal terminals for connecting with external control and/or power.

The photonic chip 111 may include a separate substrate with a semiconductor, e.g. silicon, device layer formed thereon, which includes the couplers 3₁ to 3ₙ and all connecting waveguides. Ideally the photonic integrated chip 111 comprises a silicon on insulator (SOI) structure including an upper silicon device layer, a middle silicon dioxide cladding layer, and a bottom silicon substrate. The advantage of this arrangement is that electrical controls on the photonic integrated chip 111 may control the properties of the amplifiers 101₁ to 101ₙ, e.g. wavelength and gain.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

We claim:

1. An optical amplifier device comprising:
an input port for launching an input optical signal;
a coupler including an input optically coupled to the input port, first and second input/outputs, and an output, wherein the coupler is capable of separating the input optical signal into first and second sub-beams, and outputting the first and second sub-beams via the first and second input/outputs, respectively;
a gain medium optically coupled to the first and second input/outputs, capable of amplifying the first and second sub-beams forming first and second amplified sub-beams;
a reflector for reflecting the first and second amplified sub-beams back to the coupler;
an output port optically coupled to the output for outputting the amplified optical signal; and
a first phase shifter capable of adjusting a phase of the first sub-beam and the first amplified sub-beam, so that the first amplified sub-beam combines coherently with the second amplified sub-beam causing coherent cancellation therebetween, and forming an combined amplified optical signal, whereby substantially all of the combined amplified optical signal exits the output of the coupler;
wherein the coupler is further capable of combining the first and second amplified sub-beams into the combined amplified optical signal, and outputting the combined amplified optical signal via the output to the output port.

2. The device according to claim 1, further comprising a controller for independently tuning an amount of gain provided by the gain medium to each of the first and second sub-beams to enhance coherent cancellation between the first and second sub-beams in the coupler, and reduce back reflection to the input port.

3. The according to claim 2, further comprising an optical sensor optically coupled between the input port and the coupler for determining an amount of back reflection from the combined amplified optical signal; wherein the controller is capable of tuning the first phase shifter and/or the gain of the gain medium in response to the amount of back reflection.

4. The device according to claim 2, further comprising a second phase shifter capable of adjusting the phase of the second sub-beam and second amplified sub-beam, so that the second amplified sub-beam combines coherently with the first amplified sub-beam, whereby substantially all of the amplified optical signal exits the output and the output port.

5. The device according to claim 1, further comprising a first photonic integrated chip for supporting the input port, the coupler and the output port; and a second chip for supporting the gain medium.

6. The device according to claim 1, further comprising a photonic integrated chip for supporting the input port, the coupler and the output port; wherein the photonic integrated chip includes a pit for receiving the gain medium.

7. The device according to claim 1, further comprising a band pass filter optically coupled between the input port and the coupler for passing light in the input optical signal in a selected wavelength range, and rejecting light outside the selected wavelength range.

8. The device according to claim 7, wherein the band pass filter comprises a tunable band pass filter for tuning the selected wavelength range.

9. The device according to claim 1, wherein the coupler comprises a 3 dB 2×2 coupler.

10. The device according to claim 1, further comprising:
an additional input port for launching an additional input optical signal;
an additional coupler including an additional input optically coupled to the additional input port, additional first and second input/outputs, and an additional output, wherein the additional coupler is capable of separating the additional input optical signal into additional first and second sub-beams, and outputting the additional first and second sub-beams via the additional first and second input/outputs, respectively, to the gain medium, which is also capable of amplifying the additional first and second sub-beams forming additional first and second amplified sub-beams,
wherein the reflector is also capable of reflecting the additional first and second amplified sub-beams back to the additional coupler;
wherein each additional coupler is further capable of combining the additional first and second amplified sub-beams into the additional amplified optical signal, and outputting the additional amplified optical signal via the additional output;
an additional output port optically coupled to the additional output for outputting the additional amplified optical signal; and
an additional first phase shifter capable of adjusting the phase of the additional first sub-beam and the additional first amplified sub-beam, so that the additional first amplified sub-beam combines coherently with the additional second amplified sub-beam causing coherent cancellation therebetween, whereby substantially all of the additional amplified optical signal exits the additional output and the additional output port.

11. An optical amplifier device comprising:
a first input port for launching a first input optical signal;
a first coupler including first, second, third and fourth branches, the first branch optically coupled to the first input port, wherein the first coupler is capable of separating the first input optical signal into first and second sub-beams onto the second and third branches, respectively;
a first gain medium optically coupled to the second and third branches, capable of amplifying the first and second sub-beams forming first and second amplified sub-beams, and
a first reflector for reflecting the first and second amplified sub-beams back to the coupler; and
a first output port optically coupled to the fourth branch for outputting a first amplified optical signal;
a first phase shifter capable of adjusting the phase of the first sub-beam and the first amplified sub-beam, so that the first amplified sub-beam combines coherently with the second amplified sub-beam causing coherent cancellation therebetween, whereby substantially all of the first amplified optical signal exits the fourth branch and the first output port;
wherein the first coupler is further capable of combining the first and second amplified sub-beams into the first amplified optical signal, and outputting the first amplified optical signal via the fourth branch to the first output port;
a second input port for launching a second input optical signal;
a second coupler including fifth, sixth, seventh and eighth branches, the fifth branch optically coupled to the second input port, wherein the second coupler is capable of separating the second input optical signal into third and fourth sub-beams onto the sixth and seventh branches, respectively;
a second gain medium optically coupled to the sixth and seventh branches, capable of amplifying the third and fourth sub-beams forming third and fourth amplified sub-beams;
a second reflector for reflecting the third and fourth amplified sub-beams back to the second coupler; and
a second output port optically coupled to the eighth branch for outputting a second amplified optical signal;
a second phase shifter capable of adjusting the phase of the third sub-beam and the third amplified sub-beam, so that the third amplified sub-beam combines coherently with the fourth amplified sub-beam causing coherent cancellation therebetween, whereby substantially all of the second amplified optical signal exits the eighth branch and the second output port;
wherein the second coupler is further capable of combining the third and fourth amplified sub-beams into the second amplified optical signal, and outputting the second amplified optical signal via the eighth branch to the second output port.

12. The device according to claim 11, further comprising a first controller for independently tuning an amount of gain provided by the first gain medium to each of the first and second sub-beams.

13. The device according to claim 12, further comprising a first optical sensor optically coupled between the first input port and the first coupler for determining an amount of back reflection from the first amplified optical signal; wherein the first controller is capable of tuning the first phase shifter and/or the gain of the first gain medium in response to the amount of back reflection.

14. The device according to claim 11, wherein the first and second gain medium comprise a same gain medium.

15. The device according to claim 14, further comprising: a first photonic integrated chip for supporting the first and second couplers; and a second chip optically coupled to the first chip for supporting the same gain medium.

16. The device according to claim 14, further comprising a first photonic integrated chip for supporting the first and second couplers; wherein the first photonic integrated chip includes a pit for receiving the same gain medium.

17. The device according to claim 14, further comprising:
a first band pass filter optically coupled between the first input port and the first coupler for passing light in the first input optical signal in a first selected wavelength range, and rejecting light outside the first selected wavelength range; and
a second band pass filter optically coupled between the second input port and the second coupler for passing light in the second input optical signal in a second selected wavelength range, different from the first selected wavelength range, and rejecting light outside the second selected wavelength range;
wherein the same gain medium is capable of amplifying both the first and second selected wavelength ranges.

18. The device according to claim 11, further comprising: a first photonic integrated chip for supporting the first and second couplers; a second chip optically coupled to the first chip for supporting the first gain medium; and a third chip optically coupled to the first photonic integrated chip for supporting the second gain medium.

19. The device according to claim 11, further comprising a first photonic integrated chip for supporting the first and second couplers; wherein the first photonic integrated chip includes a first pit for receiving the first gain medium; and a second pit for receiving the second gain medium.
